(19) United States
(12) Patent Application Publication
(10) Pub. No.: US 2017/0062757 A1
(43) Pub. Date: Mar. 2, 2017

(54) FLEXIBLE OLED DISPLAY AND METHOD FOR MANUFACTURING THE SAME

(71) Applicant: EVERDISPLAY OPTRONICS (SHANGHAI) LIMITED, SHANGHAI (CN)

(72) Inventor: Sisi ZHOU, SHANGHAI (CN)

(73) Assignee: EVERDISPLAY OPTRONICS (SHANGHAI) LIMITED, SHANGHAI (CN)

(21) Appl. No.: 15/208,898

(22) Filed: Jul. 13, 2016

(30) Foreign Application Priority Data
Sep. 2, 2015 (CN) 201510555705.4

(51) Int. Cl. H01L 51/52; H01L 51/00

(52) U.S. Cl. CPC H01L 51/5237; H01L 51/0097; H01L 51/003; H01L 51/5246; H01L 51/5253; H01L 2251/5338; H01L 2227/323

(57) ABSTRACT

A flexible OLED includes: a flexible substrate; a thin film transistor (TFT) array, disposed on the flexible substrate; an OLED device, disposed on the TFT array; a first encapsulation layer, disposed on the OLED device; a second encapsulation layer, disposed under the flexible substrate; and a third encapsulation layer, laterally encapsulating a peripheral portion of the first encapsulation layer to the second encapsulation layer and forming an airtight space together with the first encapsulation layer and the second encapsulation layer to seal the flexible substrate, the TFT array and the OLED device in the airtight space.

### CROSS-REFERENCE TO RELATED APPLICATIONS

This application is based upon and claims priority to Chinese Patent Application 201510555705.4, filed on Sep. 2, 2015, the entire contents of which are incorporated herein by reference.

### TECHNICAL FIELD

The present disclosure relates to the field of semiconductor device, and more particularly, to a flexible organic light emitting diode (OLED) display and a method for manufacturing the same.

### BACKGROUND

OLED displays have many advantages such as active light emitting, high contrast ratio and having no limitations on view angle over many other display devices. Particularly, flexible OLED displays are even more advantageous. Flexible OLED displays are slimmer in volume and lower in power consumption than the devices in the prior art, which may facilitate the improvement of the battery life of the device. Meanwhile, based on the characteristics of bendable and good flexibility, its durability is greatly improved over the existing screens, and thus the risk of accidental damage to the device may be reduced. Therefore, flexible OLED displays have been wildly used in the art of display technology.

Please refer to FIG. 1, which illustrates a schematic structural diagram of a longitudinal section of a flexible OLED display in the prior art. As illustrated in FIG. 1, the OLED display includes a flexible substrate 1′, a thin film transistor (TFT) array 2′, an OLED device 3′ and a thin film encapsulation layer 4′. In FIG. 1, the TFT array 2′ is disposed on the flexible substrate 1′, the OLED device 3′ is disposed on the TFT array 2′, and the thin film encapsulation layer 4′ is provided on the OLED device 3′.

An OLED device 3′ is sensitive to moisture and oxygen, and most flexible substrates 1′ have relative higher water and oxygen penetration rate than glass substrates. As illustrated in FIG. 1, moisture and oxygen may penetrate into the OLED display from the bottom portion and the periphery of the flexible OLED display. When moisture and oxygen penetrate into the OLED display and contact the OLED device 3′, adhesion between an anode and a light emitting layer of the OLED device 3′ may be deteriorated, and chemical reactions may occur in various organic film layers in the flexible OLED display. These may cause a sharp decline of the optical-electrical characteristics of the OLED device, thereby causing aging and failure of the flexible OLED display.

### SUMMARY

According to an aspect of the present disclosure, there is provided a flexible OLED display including: a flexible substrate; a TFT array disposed on the flexible substrate; an OLED device disposed on the TFT array; a first encapsulation layer disposed on the OLED device; a second encapsulation layer disposed under the flexible substrate; and a third encapsulation layer laterally encapsulating a peripheral portion of the first encapsulation layer to the second encapsulation layer and forming an airtight space together with the first encapsulation layer and the second encapsulation layer to seal the flexible substrate, the TFT array and the OLED device in the airtight space.

According to another aspect of the present disclosure, there is provided a method for manufacturing the above flexible OLED display including: forming a flexible substrate on a base; forming a TFT array on the flexible substrate; forming an OLED device on the TFT array; forming a first encapsulation layer on the OLED device; slicing the base to form a plurality of panel units; turning over the panel units and peeling off the base on the panel units; forming a second encapsulation layer at a bottom of the flexible substrate; and performing laterally encapsulating on a peripheral portion of the first encapsulation layer to the second encapsulation layer to form a third encapsulation layer, the third encapsulation layer forming an airtight space together with the first encapsulation layer and the second encapsulation layer to seal the flexible substrate, the TFT array and the OLED device in the airtight space, thereby forming the flexible OLED display.

### BRIEF DESCRIPTION OF THE DRAWINGS

Other features, objects and advantages of the present disclosure will become more apparent by describing its non-restrictive embodiments in detail with reference to the drawings.

FIG. 1 is a schematic structural diagram of the longitudinal section of the flexible OLED display in the prior art;

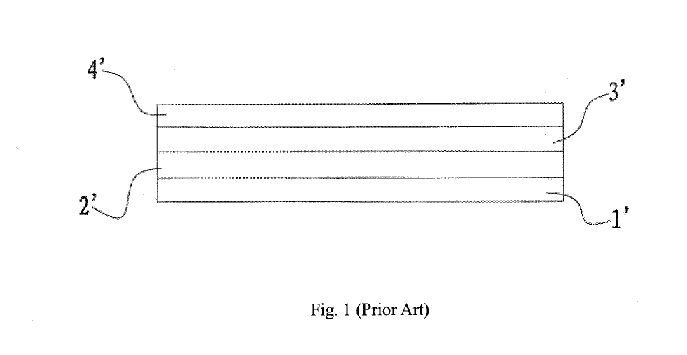

FIG. 2 is a schematic structural diagram of the longitudinal section of the flexible OLED display of the present disclosure;

FIG. 3 is a flow chart of the method for manufacturing the OLED display of the present disclosure;

FIG. 4 is a schematic structural diagram of the longitudinal section of a resulted structure after forming the flexible substrate on the base, during the manufacturing process of the OLED display of the present disclosure;

FIG. 5 is a schematic structural diagram of the longitudinal section of a resulted structure after forming the TFT array on the flexible substrate, during the manufacturing process of the OLED display of the present disclosure;

FIG. 6 is a schematic structural diagram of the longitudinal section of a resulted structure after forming the OLED device on the TFT array, during the manufacturing process of the OLED display of the present disclosure;

FIG. 7 is a schematic structural diagram of the longitudinal section of a resulted structure after forming the first encapsulation layer on the OLED device, during the manufacturing process of the OLED display of the present disclosure;

FIG. 8 is a schematic structural diagram of the longitudinal section of a resulted structure after slicing into a plurality of panel units and attaching the protection film over the first encapsulation layer of the panel unit, during the manufacturing process of the OLED display of the present disclosure;

FIG. 9 is a schematic structural diagram of the longitudinal section of a resulted structure after turning over the panel unit and peeling off the base, during the manufacturing process of the OLED display of the present disclosure; and

FIG. 10 is a schematic structural diagram of the longitudinal section of a resulted structure after forming the second encapsulation layer at a bottom of the flexible substrate, during the manufacturing process of the OLED display of the present disclosure.

### DETAILED DESCRIPTION

According to the concept of the present disclosure, the flexible OLED display includes: a flexible substrate; a TFT array disposed on the flexible substrate; an OLED device disposed on the TFT array; a first encapsulation layer disposed on the OLED device; a second encapsulation layer disposed under the flexible substrate; and a third encapsulation layer laterally encapsulating a peripheral portion of the first encapsulation layer to the second encapsulation layer and forming an airtight space together with the first encapsulation layer and the second encapsulation layer to seal the flexible substrate, the TFT array and the OLED device in the airtight space.

Hereinafter, technical content of the present disclosure will be further described with reference to the drawings and embodiments.

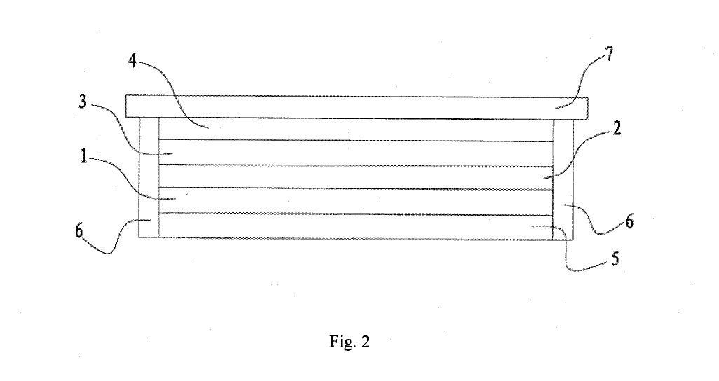

Please refer to FIG. 2, which illustrates a schematic structural diagram of the longitudinal section of the flexible OLED display of the present disclosure. As illustrated in FIG. 2, in a preferred embodiment of the present disclosure, the flexible OLED display includes a flexible substrate 1, a TFT array 2, an OLED device 3, a first encapsulation layer 4, a second encapsulation layer 5, a third encapsulation layer 6 and a protection film 7.

Preferably, the flexible substrate 1 is formed of polyimide material. Preferably, the flexible substrate 1 has a rectangular cross section.

The TFT array 2 is disposed on the flexible substrate 1. The TFT array 2 is composed of a plurality of TFTs, each of which is disposed in a pixel region of the flexible OLED display. The TFT array 2 serves to drive the OLED device 3.

The OLED device 3 is disposed on the TFT array 2 in the pixel region of the flexible OLED display. The OLED device 3 includes an anode, a light emitting layer, a cathode and the like, and the OLED device 3 may have a top emission structure or a bottom emission structure.

The first encapsulation layer 4 is disposed on the OLED device 3 and covers the OLED device 3. The first encapsulation layer 4 has a cross sectional area greater than or equal to that of the flexible substrate 1. Preferably, the first encapsulation layer 4 has a thickness of 30 nm to 200 nm. The first encapsulation layer 4 is compositely formed of any one or more of SiOₓ thin film, SiNₓ thin film or Al₂O₃ thin film. The first encapsulation layer 4 is formed on the OLED device 3 by vapor deposition means (such as evaporation).

The second encapsulation layer 5 is disposed under the flexible substrate 1. The second encapsulation layer 5 has a cross sectional area greater than or equal to that of the flexible substrate 1, which is substantially equal to that of the first encapsulation layer 4. Preferably, the second encapsulation layer 5 has a thickness of 30 nm to 200 nm. The second encapsulation layer 5 is compositely formed of any one or more of SiOₓ thin film, SiNₓ thin film or Al₂O₃ thin film. The second encapsulation layer 5 is formed under the flexible substrate 1 by vapor deposition means (such as evaporation).

The third encapsulation layer 6 laterally encapsulates a peripheral portion of the first encapsulation layer 4 to the second encapsulation layer 5 and forms an airtight space together with the first encapsulation layer 4 and the second encapsulation layer 5 to seal the flexible substrate 1, the TFT array 2 and the OLED device 3 in the airtight space. In particular, as illustrated in FIG. 2, since the cross sectional area of the first encapsulation layer 4 is substantially equal to that of the second encapsulation layer 5 and the first encapsulation layer 4 is correspondingly positioned above the second encapsulation layer 5, the third encapsulation layer 6 may be disposed around the peripheral portion of the first encapsulation layer 4 and the second encapsulation layer 5. Preferably, the third encapsulation layer 6 has a thickness of 30 nm to 200 nm. The third encapsulation layer 6 is compositely formed of any one or more of SiOₓ thin film, SiNₓ thin film or Al₂O₃ thin film The third encapsulation layer 6 is formed at the peripheral portion of the first encapsulation layer 4 and the second encapsulation layer 5 by vapor deposition means (such as evaporation). Preferably, the second encapsulation layer 5 and the third encapsulation layer 6 are formed integrally.

Further, according to the present disclosure, by the encapsulation of the first encapsulation layer 4, the second encapsulation layer 5 and the third encapsulation 6, the flexible substrate 1, the TFT array 2 and the OLED device 3 in the airtight space formed by the above three layers may be prevented from the penetration of external moisture and oxygen. Particularly, the second encapsulation layer 5 and the third encapsulation layer 6 may prevent the problem such as penetration of moisture and oxygen from the bottom portion and the periphery of the flexible OLED display existed in the flexible OLED display in the prior art. Further, deterioration of adhesion between an anode and a light emitting layer of the OLED device 3 and chemical reactions occurred in various organic film layers in the flexible OLED display may be prevented, thereby ensuring optical-electrical characteristics of the OLED device and increasing lifespan of the OLED device.

As illustrated in FIG. 2, in a preferred embodiment of the present disclosure, the flexible OLED display further includes a protection film 7. The protection film 7 is disposed on the first encapsulation layer 4. The protection film 7 is adhered to the first encapsulation layer 4 by an adhesive. The protection film 7 has a cross section area greater than or equal to that of the flexible OLED display formed after the encapsulation of the first encapsulation layer 4, the second encapsulation layer 5 and the third encapsulation layer 6. Preferably, the protection film 7 is formed of soft plastic and has a thickness of 0.05 mm to 0.5 mm.

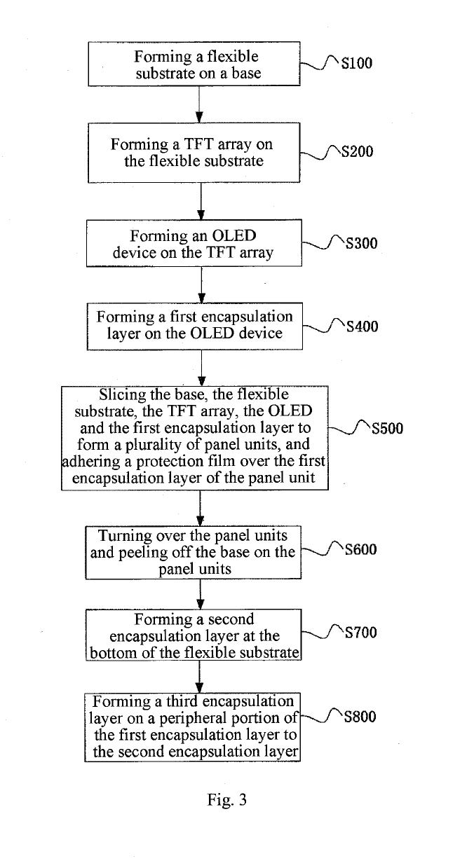

Please refer to FIGS. 3 to 10 together, which illustrate a flow chart of the method for manufacturing the flexible OLED display of the present disclosure and schematic structural diagrams of the longitudinal section of the flexible OLED display corresponding to each step in the manufacturing process, respectively. In particular, the present disclosure further provides a method for manufacturing the flexible OLED display illustrated above in FIG. 2. As illustrated in FIG. 3, the manufacturing method includes the steps as follows.

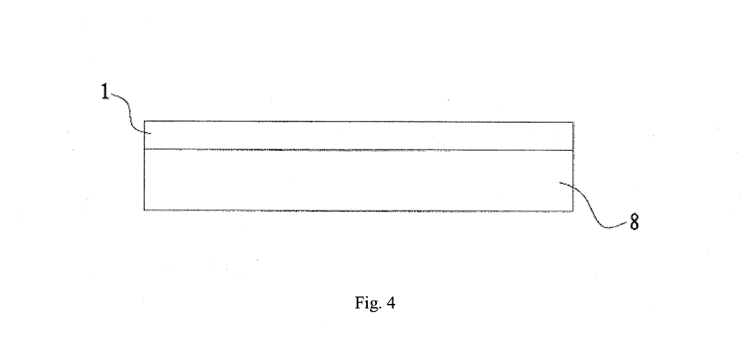

In step S100, a flexible substrate 1 is formed on a base 8, as illustrated in FIG. 4. In one embodiment, preferably, the flexible substrate 1 covers the entire base 8. The base 8 is preferably a glass base.

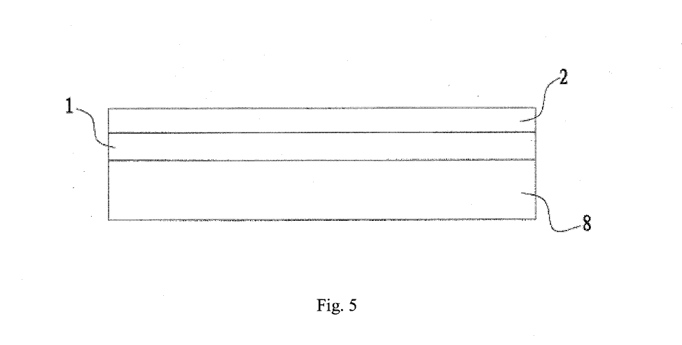

In step S200, a TFT array 2 is formed on the flexible substrate 1, as illustrated in FIG. 5. In one embodiment, the TFT array 2 includes a plurality of TFTs each of which is formed in a predetermined pixel region on the flexible substrate 1.

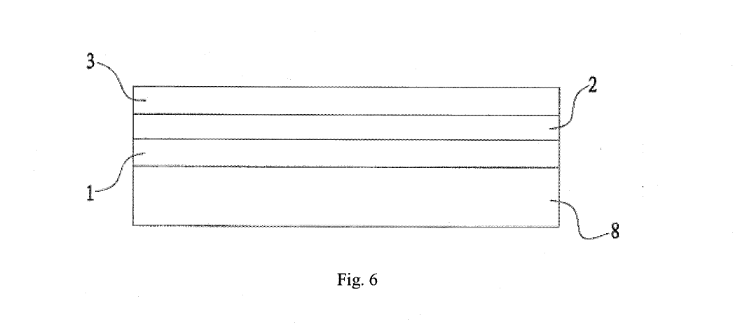

In step S300, an OLED device 3 is formed on the TFT array 2, as illustrated in FIG. 6. In one embodiment, the OLED device 3 includes an anode, a light emitting layer and a cathode. The light emitting layer sequentially includes a hole injection layer, a hole transmission layer, an organic light emitting material layer, an electron transmission layer and an electron injection layer.

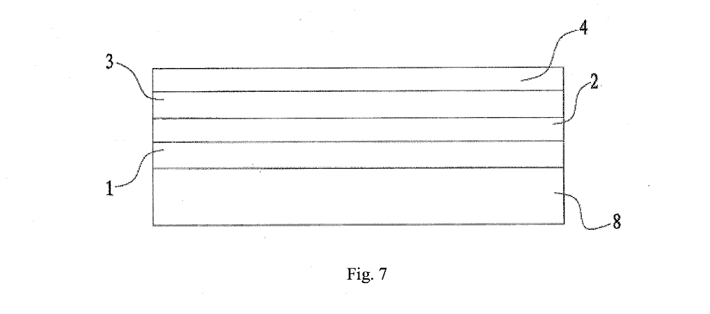

In step 400, a first encapsulation layer 4 is formed on the OLED device 3. The first encapsulation 4 covers the entire OLED device 3, as illustrated in FIG. 7.

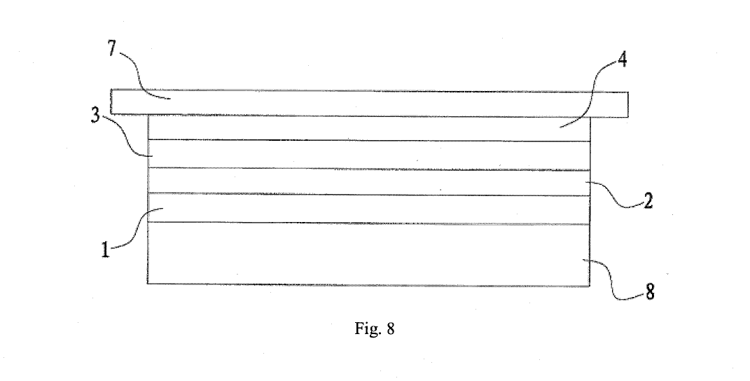

In step 500, the base 8, the flexible substrate 1, the TFT array 2, the OLED device 3 and the first encapsulation layer 4 illustrated above in FIG. 7 are sliced to form a plurality of panel units, and a protection film 7 is adhered over the first encapsulation layer 4 of the panel unit, as illustrated in FIG. 8. In one embodiment, the panel unit is in a predesigned size, which may directly correspond to a screen size of an electronic apparatus. Preferably, the protective layer 7 has a cross sectional area greater than that of the panel unit. That is, the protective layer 7 has a cross sectional area greater than that of the flexible substrate 1, the TFT array 2, the OLED device 3 and the first encapsulation layer 4 of the panel unit.

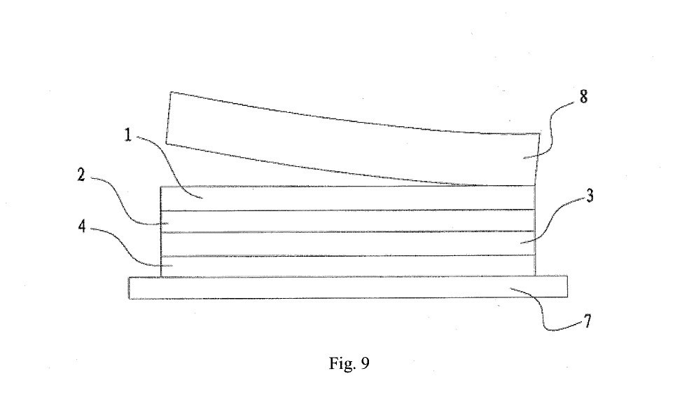

In step 600, the panel unit in the above FIG. 8 is turned over, and the base 8 on the panel unit is peeled off, as illustrated in FIG. 9. In particular, the base 8 formed of glass material is required to be peeled off from the surface of the flexible substrate 1 for the flexibility requirement of the flexible OLED display.

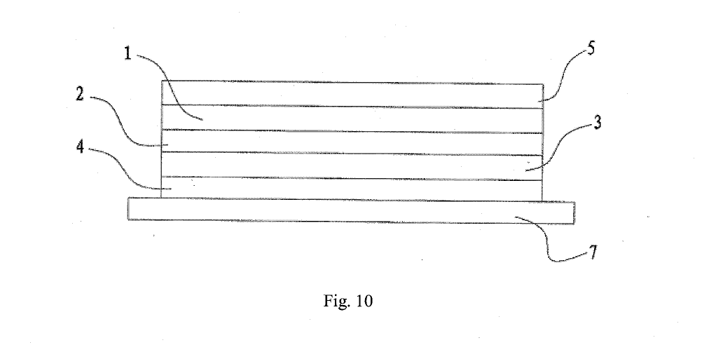

In step 700, a second encapsulation layer 5 is formed at the bottom of the flexible substrate 1. As illustrated in FIG. 10, since the panel unit is turned over, the bottom of the flexible substrate 1 is a top of the flexible substrate 1 in FIG. 10. The second encapsulation layer 5 covers the entire flexible substrate1, and has a size substantially equal to that of the first encapsulation layer 4.

In step 800, a third encapsulation layer 6 is formed by laterally encapsulating a peripheral portion of the first encapsulation layer 4 to the second encapsulation layer 5. In one embodiment, the third encapsulation layer 6 forms an airtight space together with the first encapsulation layer 4 and the second encapsulation layer 5 to seal the flexible substrate 1, the TFT array 2 and the OLED device 3 in the airtight space, thereby forming a flexible OLED display as illustrated in FIG. 2.

In addition, in a preferred embodiment of the present disclosure, the above step 700 and the step 800 may be performed simultaneously. In particular, in the processes of forming the second encapsulating layer 5 and the third encapsulation layer 6, since the panel unit that is turned over has its protection film 7 positioned at the bottom thereof and the protection film 7 has a cross sectional area greater than that of the panel unit, while forming the second encapsulation layer 5 on the bottom of the flexible substrate 1 by vapor deposition (evaporation), the third encapsulation layer 6 may be formed at the peripheral portion of the first encapsulation layer 4 and the substrate 1, as long as the area and time of the vapor deposition (evaporation) is controlled such that the area of the vapor deposition (evaporation) is greater than the cross sectional area of the substrate 1 while smaller than the cross sectional area of the protection film 7. Accordingly, the second encapsulating layer 5 and the third encapsulation layer 6 may be formed simultaneously, which will not be repeated herein.

The present disclosure has been described above with reference to the preferred embodiments, however, they are not provided to limit the present disclosure. Various modifications and amendments are available to those skilled in the art without departing the scope and spirit of the present disclosure. Accordingly, the protection scope of the present disclosure is defined only in the claims.

What is claimed is:

1. A flexible organic light emitting diode (OLED) display comprising:
a flexible substrate;
a thin film transistor (TFT) array, disposed on the flexible substrate;
an OLED device, disposed on the TFT array;
a first encapsulation layer, disposed on the OLED device;
a second encapsulation layer, disposed under the flexible substrate; and
a third encapsulation layer, laterally encapsulating a peripheral portion of the first encapsulation layer to the second encapsulation layer and forming an airtight space together with the first encapsulation layer and the second encapsulation layer to seal the flexible substrate, the TFT array and the OLED device in the airtight space.

2. The flexible OLED display according to claim 1, wherein each of the first encapsulation layer, the second encapsulation layer and the third encapsulation layer is compositely formed of any one or more of SiOₓ thin film, SiNₓ thin film or Al₂O₃ thin film.

3. The flexible OLED display according to claim 2, wherein the first encapsulation layer has a thickness of 30 nm to 200 nm.

4. The flexible OLED display according to claim 2, wherein the second encapsulation layer has a thickness of 30 nm to 200 nm.

5. The flexible OLED display according to claim 2, wherein the third encapsulation layer has a thickness of 30 nm to 200 nm.

6. The flexible OLED display according to claim 1, further comprising a protection film disposed on the first encapsulation layer.

7. The flexible OLED display according to claim 6, wherein the protection film is formed of soft plastic.

8. The flexible OLED display according to claim 6, wherein the protection film has a thickness of 0.05 mm to 0.5 mm.

9. The flexible OLED display according to claim 1, wherein the flexible substrate is formed of polyimide material.

10. The flexible OLED display according to claim 1, wherein the second encapsulation layer and the third encapsulation layer are formed integrally.

11. A method for manufacturing a flexible OLED display, comprising:
forming a flexible substrate on a base;
forming a TFT array on the flexible substrate;
forming an OLED device on the TFT array;
forming a first encapsulation layer on the OLED device;
slicing the base to form a plurality of panel units;
turning over the panel units and peeling off the base on the panel units;
forming a second encapsulation layer at a bottom of the flexible substrate; and
performing laterally encapsulating on a peripheral portion of the first encapsulation layer to the second encapsulation layer to form a third encapsulation layer, the third encapsulation layer forming an airtight space together with the first encapsulation layer and the second encapsulation layer to seal the flexible substrate, the TFT array and the OLED device in the airtight space, thereby forming the flexible OLED display.

12. The method according to claim 11, wherein prior to turning over the panel units, a protection film is attached over the first encapsulation layer.

13. The method according to claim 12, wherein the third encapsulation layer is formed on the protection film simultaneously with the forming of the second encapsulation layer.

14. The method according to claim 11, wherein each of the first encapsulation layer, the second encapsulation layer and the third encapsulation layer is compositely formed of any one or more of SiOₓ thin film, SiNₓ thin film or Al₂O₃ thin film

15. The method according to claim 14, wherein the first encapsulation layer is formed to a thickness of 30 nm to 200 nm.

16. The method according to claim 14, wherein the second encapsulation layer is formed to a thickness of 30 nm to 200 nm.

17. The method according to claim 14, wherein the third encapsulation layer is formed to a thickness of 30 nm to 200 nm.

18. The method according to claim 12, wherein the protection film is formed of soft plastic.

19. The method according to claim 12, wherein the protection film is formed to a thickness of 0.05 mm to 0.5 mm.

20. The method according to claim 11, wherein the flexible substrate is formed of polyimide material.
